(19) United States
(12) Patent Application Publication
(10) Pub. No.: US 2007/0285157 A1
(43) Pub. Date: Dec. 13, 2007

(54) Distribution of Radio-Frequency Signals in an Electronic Circuit

(75) Inventors: Ernst Bressau, Singapore (SG); Johannes Petrus Martinus Antonius Alphonsus Teijssen, Geldrop (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: Koninklijke Philips Elecronics N.V., 5621 BA Eindhoven (NL)

(21) Appl. No.: 10/555,834

(22) PCT Filed: May 5, 2004
(86) PCT No.: PCT/IB04/50583

§ 371 Date: Jun. 22, 2007

(30) Foreign Application Priority Data
May 8, 2003 (IB) 03/05199

(51) Int. Cl. H03F 21/00

(52) U.S. Cl. 330/1 R

(57) ABSTRACT

The invention relates to the distribution of a radio-frequency signal to various modules (20, 30, 40) on a printed circuit board (10). The radio-frequency signal supplied via an antenna plug (11) is led over a multi-section (12, 13, 14, 15) line, a respective decoupler (32) being inserted between two sections (13, 14). In addition, between two sections (13, 14) an amplifier (33) may optionally be provided for compensating for signal losses, and/or a switch (34) for separating non-active modules.

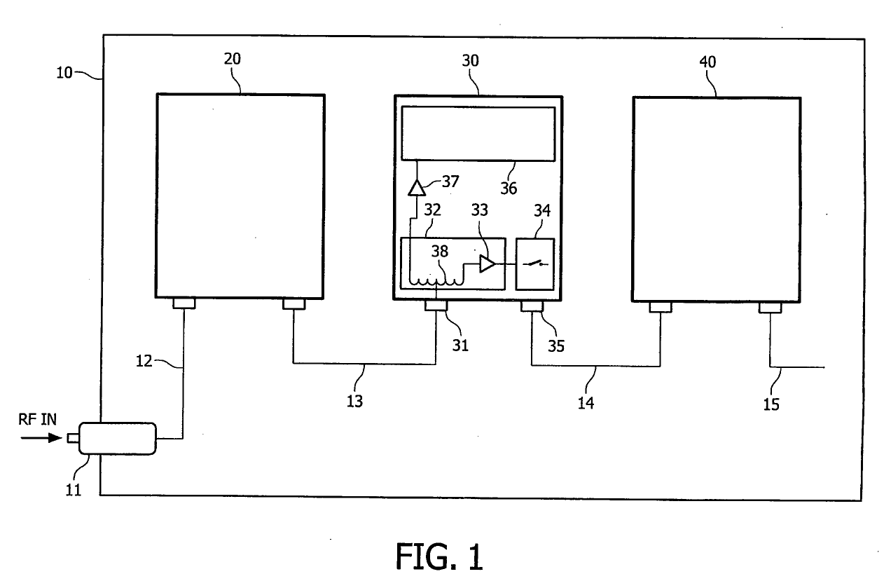

The invention relates to an electronic circuit comprising modules on a printed circuit board to which a radio-frequency signal is to be distributed.

Electric radio-frequency signals are particularly used as carriers for audio data and/or video data. In contemporary consumer electronic appliances the situation increasingly occurs that within the same appliance various modules such as, for example, tuner or receiver are provided for processing the signals, to which modules the radio-frequency signal is to be applied. In this case each module can individually be supplied with the radio-frequency signal via an external antenna cable (for example via an inserted signal divider). This procedure is relatively expensive because each module has to have its own antenna plug and a separate, external cabling is necessary. This is particularly the case if the various modules are installed on the same printed circuit board.

U.S. Pat. No. 4,769,618 has disclosed a circuit for distributing a microwave signal to various outputs, in which inserted impedances and amplifiers provide a practically lossless distribution of the signal. The circuit, however, is only suitable for a signal distribution in the microwave frequency range and the whole circuit is accommodated in a shielded housing. The subsequent distribution would then take place either in the shielded (housing) application or via shielded cables. Furthermore, the microwave technique cannot be used for the frequency range of radio and television signals. When used with these frequencies, such a circuit would be the cause of strong signal losses and problems caused by interaction with other components.

Against this background it was an object of the present invention to provide a circuit for distributing radio-frequency signals to a plurality of modules on a printed circuit board, in which circuit problems caused by signal interference are avoided to the maximum possible extent.

This object is achieved by an electronic circuit having the characteristic features of claim 1. Advantageous embodiments are contained in the dependent claims.

The electronic circuit according to the invention has on a printed circuit board at least two modules for processing a radio-frequency signal. A radio-frequency signal is then understood to be an electromagnetic signal from a frequency range beyond about 10 kHz, preferably from a frequency range of 50 MHz to 1 GHz. In the circuit the line that leads to the modules on the printed circuit board and carries the radio-frequency signal when in operation and is consequently referred to as “RF” line hereinafter, is subdivided into at least two sections which are connected by a decoupler. The decoupler then provides that the radio-frequency signal is transferred from one section of the line to the other sections, but that this is effected, for example, in a DC-isolated way and with impedance matching. The decoupler preferably jointly has the function of splitter, so that it can divide an incoming signal over (at least) two outputs.

The RF line which comprises two or more sections successively connected by decouplers may run over the printed circuit board particularly along all the modules of the printed circuit board and supply them with a radio-frequency signal. All the modules of the printed circuit board can thus be reached via a single external cable terminal and an antenna plug. At the same time the subdivision of the RF line into shorter sections decoupled from each other is advantageous in that the line does not work as a long antenna. It thus radiates neither radio-frequency signals, which would interfere with other components, nor captures interference signals from its environment. These problems may thus be avoided or at least reduced considerably without an expensive and hard-to-install shielding of the RF line on a printed circuit board being necessary.

In accordance with a preferred embodiment of the circuit, at least one of the modules has an input and an output which are connected via a decoupler, the input being connected to a first section of the RF line and the output being connected to a second section of the RF line. A radio-frequency signal present on the first section of the RF line is thus applied to the module through the input and simultaneously transferred via the decoupler to the second, subsequent section of the RF line. The decoupler integrated with the module then provides the desired decoupling of the two successive sections of the RF line.

According to a further embodiment of the module described hereinbefore, this module may be arranged for separating said output from said input if the radio-frequency signal in the first section of the RF line is not needed by any further module which is arranged downstream of the output or if no further module is connected, respectively. The separation may be achieved more particularly in that between the input and the output of the module a controllable switch element such as, for example, a switching transistor is arranged which can be opened as required. In the cases where the radio-frequency signal is no longer needed by modules later in the circuit, first no radio-frequency signal at all is fed to the respective line section of the RF line as a result of the separation. Interference caused by the radiating effect of this section is thus avoided from the start.

According to a further embodiment of the module described above an amplifier may be arranged between the input and the output of the module, more particularly between the decoupler and the output of the module. The amplifier amplifies the radio-frequency signal before it is fed to the next section of the RF line, in order to cancel signal losses which have meanwhile occurred.

With the amplifier mentioned above may be integrated a switch element by which the above separation between input and output may be effected.

The modules of the electronic circuit may be, in principle, any module that is provided for processing radio-frequency signals. More particularly, the modules may be tuners which are capable of separating a signal portion from a carrier frequency in an incoming radio-frequency signal.

The printed circuit board of the application may optionally be a multilayer PCB where the signal supply between the modules preferably takes place in the inner layers of the printed circuit board. The upper layers may then be used as an additional shielding.

In the following the invention will be explained by way of example with reference to a Figure.

The sole FIGURE diagrammatically shows an electronic circuit with a printed circuit board and three radio-frequency modules.

The printed circuit board 10 shown in the Figure and having three modules 20, 30 and 40 may be provided, for example, in an audio or video appliance such as, for example, an STB (set top box) or a television set. The modules 20, 30, 40 may particularly be tuners which are provided, for example, for performing a PIP function (picture-in-picture) in a television set.

The printed circuit board 10 has an antenna plug 11 to which may be connected an external antenna cable (not shown) for the supply of a radio-frequency signal to be processed. The radio-frequency signal is then distributed over the modules 20, 30, 40 to be connected by a RF line 12, 13, 14, 15. It should then be taken into account that if a rather long unshielded line is led over a printed circuit board, problems may arise with the electromagnetic compatibility (EMC) if a radio-frequency signal is fed to the line. The line then works both as a transmitting antenna which radiates the supplied radio-frequency signal and thus interferes with other components or appliances, and as a receiving antenna which captures electromagnetic waves from the environment and thus causes interference with the radio-frequency signal to be transported.

To solve these problems, the RF line in the circuit shown in the Figure is subdivided into a plurality of short sections 12, 13, 14, 15. The sections connect in a chain-like fashion only two modules each time 20/30 or 30/40 or the antenna plug 11 to a first module 20. The section 15 starting from the last module 40 of the chain ends unused in the example shown.

As is shown in detailed manner for the middle module 30, for each module a section (13) of the line is connected to an input 31 and the next section (14) to an output 35, the input 31 and the output 35 being interconnected via a decoupler 32. The decoupler 32 provides that the successive sections 13, 14 cannot work as one coherent antenna. The radiation problems described above or the reception of interference signals respectively, are thus avoided or strongly reduced respectively. In the example shown the decoupler 32 also has a splitter function. A coil 38 with a center tap is then provided as a splitter. Alternatively, also a transmitter (two or more coupled coils) could be used. For the decoupling is necessary a transistor stage which is arranged as an amplifier 33 in the example shown. The amplifier 33, which may particularly be a low-noise amplifier, can compensate for signal attenuations which are generated, for example, by the decoupler 32.

As may be further detected in the Figure also the actual tuner circuit 36 is connected to the decoupler 32 via an amplifier 37. This tuner circuit may also be connected directly to the input 31. Furthermore, the radio-frequency signal may be led to the output 35 downstream of the decoupler 32 by an on/off-switch 34.

The on/off-switch 34 may be opened if the next module 40 is inactive and thus needs to have a radio-frequency signal on its input. The opening of the switch 34 then avoids the radio-frequency signal ending up in the line section 14 between the modules 30 and 40, so that this section 14 cannot generate electromagnetic interference. An on/off-switch may also be included in the last module 40 of the chain and be opened continuously to keep the line section provided there as the standard and connected to the output free from signals. By switching off line sections that are not needed, not only the electromagnetic compatibility is improved but also the power consumption of the whole circuit is reduced.

The on/off-switch 34 may be realized as a separate component, as is shown. However, it may also be integrated with the amplifier 33. Furthermore, a separation between the input 34 and the output 35 of a module 30 may also be achieved by turning off the amplifier 33.

### LIST OF REFERENCES

10 printed circuit board
11 antenna plug
12, 13,
14, 15 sections of the RF line
20, 30,
40 tuner module
31 input
32 decoupler
33 amplifier
34 on/off-switch
35 output
36 tuner circuit
37 amplifier
38 coil

1. An electronic circuit comprising at least two modules (20, 30, 40) for processing a radio-frequency signal and mounted on a printed circuit board (10), the RF line on the printed circuit board and leading to the modules being divided into at least two sections (12, 13, 14, 15) which are connected by a decoupler (32), the decoupler preferably also having a splitter function.

2. A circuit as claimed in claim 1, characterized in that at least one of the modules (30) has an input (31) and an output (35) which are connected to each other via a decoupler (32), the input (31) being connected to a first section (13) and the output to a second section (14) of the RF line.

3. A circuit as claimed in claim 2, characterized in that the module (30) is arranged for separating the output (35) from the input (31) if the radio-frequency signal is not needed by any further module downstream of the output.

4. A circuit as claimed in claim 2, characterized in that between the input (31) and the output (35) of the module (30) a switch element (34) is arranged for selectively separating input and output.

5. A circuit as claimed in claim 2, characterized in that an amplifier (33) is arranged between the input (31) and the output (35) of the module (30).

6. A circuit as claimed in claim 5, characterized in that the amplifier (33) is arranged between the decoupler (32) and the output (35) of the module (30).

7. A circuit as claimed in claim 4, characterized in that the switch element is integrated with the amplifier.

8. A circuit as claimed in claim 1, characterized in that at least one of the modules (20, 30, 40) is a tuner.

9. A circuit as claimed in claim 1, characterized in that the radio-frequency signal is found in a frequency range from 50 MHz to 1 GHz.

10. A circuit as claimed in claim 1, characterized in that the printed circuit board (10) is a multilayer board and that the signal supply (12, 13, 14, 15) between the modules is found in the inner layers of the printed circuit board.
